(19) United States
(12) Patent Application Publication
(10) Pub. No.: US 2007/0209196 A1
(43) Pub. Date: Sep. 13, 2007

(54) Slider row bar de-bond fixture

(75) Inventors: Shing Cheong Lau, Hong Kong (CN); Wai Kwong Lo, Hong Kong (CN)

Correspondence Address: NIXON & VANDERHYE, PC, 901 NORTH GLEBE ROAD, 11TH FLOOR, ARLINGTON, VA, 22203, US

(73) Assignee: SAE Magnetics (H.K.) Ltd., Hong Kong (CN)

(21) Appl. No.: 11/708,673

(22) Filed: Feb. 21, 2007

(30) Foreign Application Priority Data
Feb. 21, 2006 (CN) 200610004197.1

(51) Int. Cl. G11C 5/12; G11B 5/127

(52) U.S. Cl. 29/737; 29/729; 29/603.07

(57) ABSTRACT

A slider row bar de-bond fixture has a base plate; a row of separator walls formed on a top surface of the base plate and spaced one another for separating a plurality of slider row bars; and a plurality of grooves defined between the adjacent separator walls for receiving the slider row bars respectively. Each of the separator walls has a free top end with a smaller depth than its bottom end. Preferably, each of the separator walls has a structure of trapezoid or triangular form in cross section. The slider row bar de-bond fixture occupy a little room and more importantly, receive the debonded slider row bars more safely and without overlapping.

### FIELD OF THE INVENTION

The present invention relates to an equipment for manufacturing sliders used in disk drive, and more particularly to a de-bond fixture for separating and receiving a plurality of debonded slider row bars.

### BACKGROUND OF THE INVENTION

Disk drives are familiar information storage devices that use magnetic media, such as a disk, to store data and a movable read/write slider flying over the disk to selectively read data from and write data to the disk.

At present, a method of manufacturing sliders comprises steps of: (1) cutting a wafer into a plurality of slider row bars; (2) surface processing (such as lapping) and shaping (such as forming crown) the slider row bars; (3) bonding the slider row bars together by epoxy, placing the bonded slider row bars on a jig and then forming patterns on the slider row bar; (4) solving the epoxy on the slider row bars and the jig by solvent, such as NMP, to debond the slider row bars; (5) cutting the debonded slider row bar into a plurality of individual slider bodies and finally surface-handling the slider bodies to form the desired sliders.

The following shows a more detail explanation of how the slider row bar is debonded. As shown in FIGS. 3 and 4, a row of slider row bars 20 are bonded together by epoxy (not labeled) and adhered to a jig 30. Because of the existence of the epoxy, a gap 22 with a width of about 60 μm is formed between the adjacent slider row bars 20. Then, the jig 30 together with the slider row bars 20 thereon are inverted and immersed in solvent for dissolving the epoxy. As shown in FIGS. 5A and 5B, the slider row bars 20 are debonded or separated, and a plane de-bond fixture 100 is used to receive the debonded slider row bars 20.

However, as shown in FIG. 5B, the separated row bars debonded by the above-mentioned method are easily to overlap one another, which attributes the disadvantages of damaging the slider row bars 20 and, in turn, affecting the quality of the sliders produced from the slider row bars 20, and finally affecting the read/write performance of the sliders.

In order to solve these problems, a de-bond fixture 40 is used to receive the separated slider row bars 20. As shown in FIG. 6, a row of rectangular guiding walls 42 are formed on the top surface of the de-bond fixture 40. The width of each of the rectangular guiding walls 42 is less than that of the gap 22 between the adjacent row bars (referring to FIG. 4). When debonding the slider row bars 20, the slider row bars 20 align with grooves 45 defined between adjacent guiding walls 42 respectively and drop into the respective grooves 45, so the slider row bars 20 are separated by the guiding walls 42, thereby protected from overlapping one another.

However, the guiding walls 42 of de-bond fixture 40 are too thin, for example less than 60 μm in thickness, to be easily damaged. In addition, once the guiding walls 42 are slightly tilted, the slider row bars 20 would not be successfully dropped into the grooves 45, and in such cases the slider row bars 20 might still overlap one another.

Hence, providing a slider row bar de-bond fixture to overcome the disadvantages mentioned above is necessary.

### SUMMARY OF THE INVENTION

Accordingly, an object of the present invention is to provide a slider row bar de-bond fixture which occupy a little room and receive the debonded slider row bars more safely and without overlapping.

To achieve the above-mentioned objects, a slider row bar de-bond fixture comprises a base plate; a row of separator walls formed on a top surface of the base plate and spaced one another for separating a plurality of slider row bars; and a plurality of grooves defined between the adjacent separator walls for receiving the slider row bars respectively. Each of the separator walls has a free top end with a smaller depth than its bottom end. In the present invention, each of the separator walls has such a structure that it is much easier for receiving the row bars into the grooves. In addition, it becomes much easier to insert the separator walls into the gaps between the slider row bars due to the structure, so that the dropped row bars can be protected from overlapping one another. Furthermore, since the bottom end of each separator wall is thicker than the free top end, the separator walls are tougher than conventional rectangular separator walls so as to avoid deformation after crashing or long time soaking in solvent. Finally, due to the above-mentioned structure of the de-bond fixture, the de-bond fixture can load the row bar in a slope surface so that a depth of the groove, also a depth of the fixture can be smaller than that of the conventional de-bond fixture, that is to say, only a little room is occupied by the de-bond fixture.

According to an embodiment of the present invention, each of the separator walls has a structure of triangular form in cross section. In another embodiment, each of the separator walls is designed to have a structure of trapezoid in cross section. More concretely, each of the separator walls has two side surfaces, one of which is a slope surface, and the other of which is designed to be vertical so as to server as a reference surface to facilitate aligning the row bars with the grooves.

Preferably, an angle defined by the two side surfaces of each separator wall ranges from 15 degrees to 80 degrees, which ensures that the sharpened top end of the separator wall can be easily inserted into the gaps between the row bars, and that the grooves receive the debonded slider row bars more safely and easily.

In the invention, the slider row bar de-bond fixture is preferably made of antistatic material in order to prevent electric static discharge (ESD) during manufacturing process, thereby protecting the row bar from being damaged by ESD.

Other aspects, features, and advantages of this invention will become apparent from the following detailed description when taken in conjunction with the accompanying drawings, which are a part of this disclosure and which illustrate, by way of example, principles of this invention.

### BRIEF DESCRIPTION OF THE DRAWINGS

FIG. 1 is a perspective view of a slider row bar de-bond fixture according to an embodiment of the present invention, also showing slider row bars carried on the de-bond fixture.

FIG. 2 is a partially enlarged, side view of the slider row bar de-bond fixture shown in FIG. 1.

FIG. 2A is a partially enlarged, side view of another embodiment of a slider row bar de-bond fixture according to the present invention.

FIG. 3 is a perspective view of slider row bars adhered to a jig according to the prior art.

FIG. 4 is an enlarged view of part IV of FIG. 3.

FIG. 5A shows the slider row bars separating from the jig and dropped onto a plane de-bond fixture according to the prior art.

FIG. 5B shows the slider row bars overlapping one another after dropped onto the plane de-bond fixture shown in FIG. 5A.

FIG. 6 is a perspective view of a de-bond fixture with separator walls according to the prior art, also showing slider row bars carried thereon.

### DETAILED DESCRIPTION OF ILLUSTRATED EMBODIMENTS

Various preferred embodiments of the invention will now be described with reference to the figures, wherein like reference numerals designate similar parts throughout the various views. As indicated above, the invention is directed to a slider row bar de-bond fixture, which comprises a base plate; a row of separator walls formed on a top surface of the base plate and spaced one another for separating a plurality of slider row bars; and a plurality of grooves defined between the adjacent separator walls for receiving the slider row bars respectively. Each of the separator walls has a free top end with a smaller depth than its bottom end. Such a structure facilitates the separator walls inserting into respective gaps between the slider row bars and enables the separator walls tough enough to separate or disconnect the slider row bars. Additionally, because the upper opening of each groove is larger than the lower opening thereof, it will help to receive the slider row bars safely and avoid the slider row bars overlapping one another.

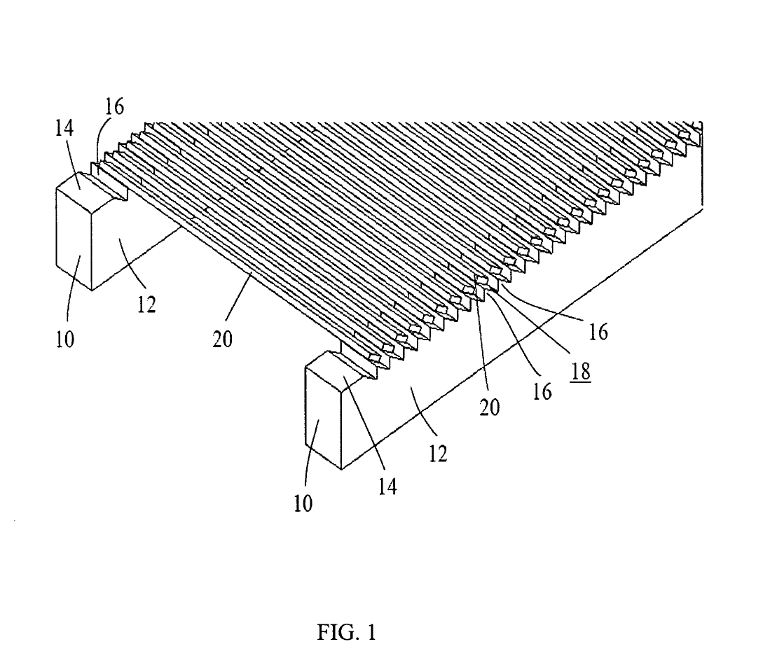

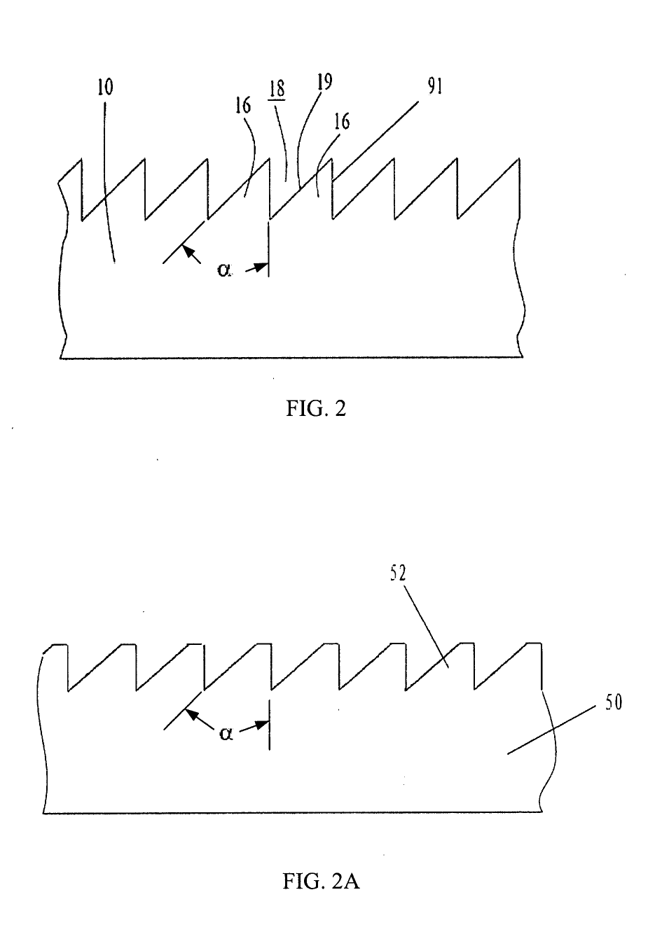

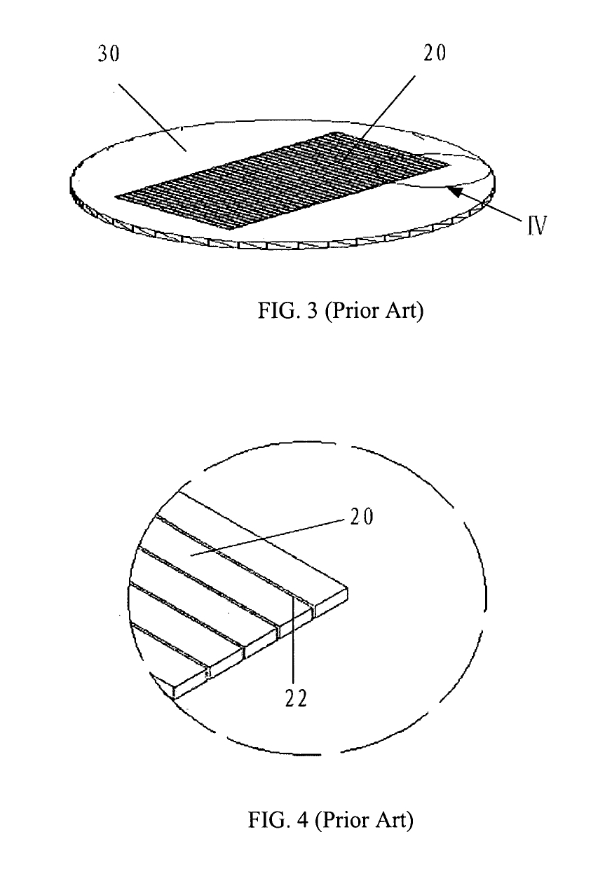

Referring to FIG. 1 and FIG. 2, according to an embodiment of this invention, a slider row bar de-bond fixture 10 includes a base plate 12. A row of separator walls 16 are formed on a top surface 14 of the base plate 12, and a plurality of grooves 18 are defined between the adjacent separator walls 16. In the embodiment, each of the separator walls 16 has a same structure. One side surface of the separator wall 16 is a slope surface 19, and the other side surface thereof is a vertical plane surface 91. Thus each of the separator walls 16 is tapered at its top end, and accordingly, the row of the separator walls 16 as a whole shapes as serration. In the embodiment, as shown in FIG. 2, each separator wall 16 is designed to have a structure of triangular form in cross section. An angle α defined by the two side surfaces of each separator wall 16 may range from 15 degrees to 80 degrees so long as the slider row bars 20 can slide down the slope 19 and safely drop into the respective grooves 18.

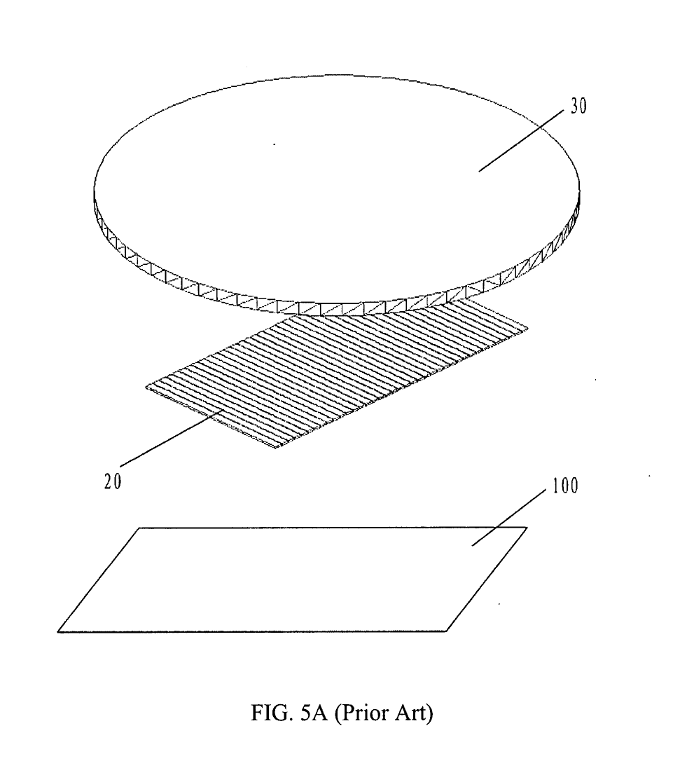

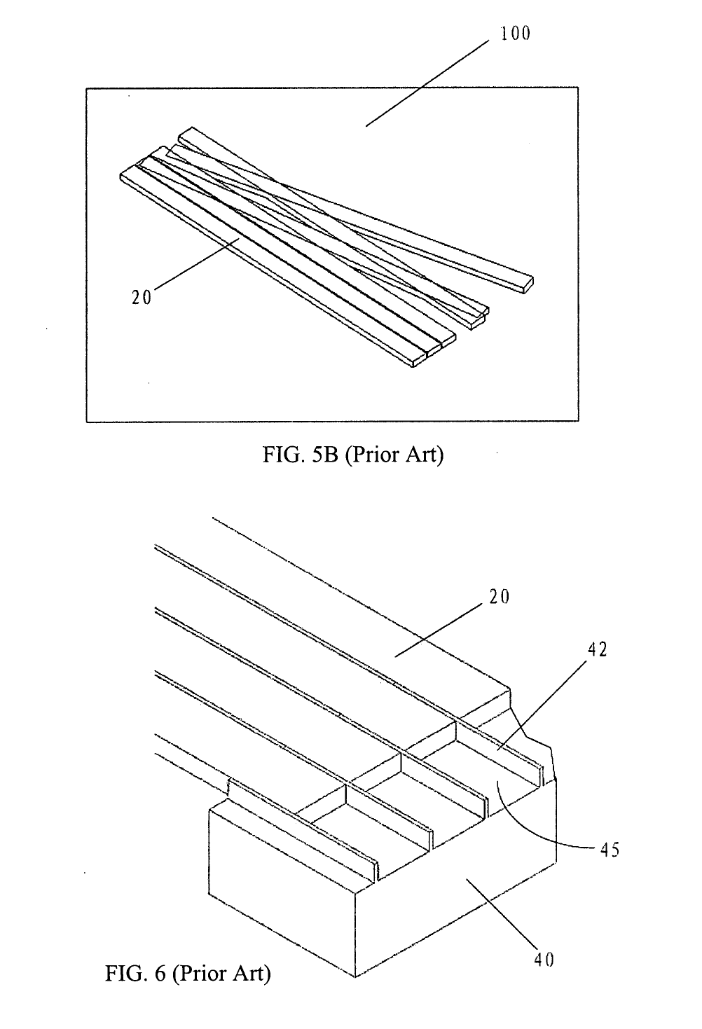

When debonding the slider row bars 20, referring to FIG. 1 and FIG. 5A, firstly, the jig 30 and the row bars 20 adhered thereon are immersed into the solvent for dissolving epoxy, and then the slider row bar de-bond fixture 10 of the invention are provided; secondly, aligning the slider row bars 20 with the grooves 18 formed on the de-bond fixture 10; finally, when separated from the jig 30, each row bar 20 approaches the slope 19 of the corresponding separator wall 16, slides down the slop 19, and then drops into the respective groove 18.

As best shown in FIG. 1, the debonded row bars 20 are orderly arranged on the de-bond fixture 10 and separated by separator walls 16, thereby effectively preventing the row bars 20 from overlapping one another. Moreover, as each separator wall 16 has a free top end with a smaller depth than its bottom end, the upper opening of each groove 18 is larger than the lower opening thereof, thereby it is much easier for the grooves 18 to receive the row bars 20, which gives another reason for the de-bond fixture 10 able to protect the dropped row bars 20 from overlapping one another. In addition, since the bottom end of each separator wall 16 is thicker than the free top end, the separator walls 16 is rather tougher so as to avoid deformation after crashing or long time soaking in solvent.

In the present invention, the side surface 91 of each separator wall 16 is designed to be vertical in order to serve as a reference surface to facilitate aligning the row bars 20 with the respective grooves 18. It will be appreciated that both side surfaces of the separator wall 16 can also be inclined.

As shown in FIG. 2A, the separator walls 52 of a slider row bar de-bond fixture 50 according to another embodiment of the invention is designed as to has a structure of trapezoid in cross section. Understandably, this de-bond fixture 50 can also gain advantageous effects similar to the above-mentioned de-bond fixture 10. Of course, the angle α defined by the two side surfaces can also range from 15 degrees to 80 degrees.

In the invention, the slider row bar de-bond fixtures mentioned above are preferably made of antistatic material in order to prevent electric static discharge (ESD) during manufacturing process, thereby preventing the slier row bars 20 from being damaged by ESD.

While the invention has been described in connection with what are presently considered to be the most practical and preferred embodiments, it is to be understood that the invention is not to be limited to the disclosed embodiments, but on the contrary, is intended to cover various modifications and equivalent arrangements included within the spirit and scope of the invention.

What is claimed is:

1. A slider row bar de-bond fixture comprising:
a base plate;
a row of separator walls formed on a top surface of the base plate and spaced one another for separating a plurality of slider row bars; and
a plurality of grooves defined between the adjacent separator walls for receiving the slider row bars respectively;
wherein each of the separator walls has a free top end with a smaller depth than its bottom end.

2. The slider row bar de-bond fixture as claimed in claim 1, wherein each of the separator walls has a structure of trapezoid in cross section.

3. The slider row bar de-bond fixture as claimed in claim 1, wherein each of the separator walls has a structure of triangular form in cross section.

4. The slider row bar de-bond fixture as claimed in claim 1, wherein each of the separator walls has two side surfaces, and one of the side surfaces is a slope surface.

5. The slider row bar de-bond fixture as claimed in claim 1, wherein each of the separator walls has two side surfaces, and an angle defined by the two side surfaces ranges from 15 degrees to 80 degrees.

6. The slider row bar de-bond fixture as claimed in claim 1, wherein the slider row bar de-bond fixture is made of antistatic material.
